(19) United States
(12) Patent Application Publication
(10) Pub. No.: US 2013/0206068 A1
(43) Pub. Date: Aug. 15, 2013

(54) LINEAR PECVD APPARATUS

(71) Applicants: Jozef KUDELA, San Jose, CA (US); Suhail ANWAR, Saratoga, CA (US); Carl A. SORENSEN, Morgan Hill, CA (US); Douglas TRUONG, San Jose, CA (US); John M. WHITE, Hayward, CA (US)

(72) Inventors: Jozef KUDELA, San Jose, CA (US); Suhail ANWAR, Saratoga, CA (US); Carl A. SORENSEN, Morgan Hill, CA (US); Douglas TRUONG, San Jose, CA (US); John M. WHITE, Hayward, CA (US)

(21) Appl. No.: 13/764,832

(22) Filed: Feb. 12, 2013

Related U.S. Application Data
(60) Provisional application No. 61/597,978, filed on Feb. 13, 2012.

(51) Int. Cl. C23C 16/511

(52) U.S. Cl. CPC C23C 16/511
USPC 118/723 MW; 118/723 R

(57) ABSTRACT

The present invention generally relates to a linear PECVD apparatus. The apparatus is designed to process two substrates simultaneously so that the substrates share plasma sources as well as gas sources. The apparatus has a plurality of microwave sources centrally disposed within the chamber body of the apparatus. The substrates are disposed on opposite sides of the microwave sources with the gas sources disposed between the microwave sources and the substrates. The shared microwave sources and gas sources permit multiple substrates to be processed simultaneously and reduce the processing cost per substrate.

### CROSS-REFERENCE TO RELATED APPLICATIONS

This application claims benefit of U.S. Provisional Patent Application Ser. No. 61/597,978 (APPM/16222L), filed Feb. 13, 2012, which is herein incorporated by reference.

### BACKGROUND OF THE INVENTION

1. Field of the Invention

Embodiments of the present invention generally relate to a linear plasma enhanced chemical vapor deposition (PECVD) apparatus.

2. Description of the Related Art

Chemical vapor deposition (CVD) is a process whereby chemical precursors are introduced into a processing chamber, chemically react to form a predetermined compound or material, and deposit the compound or material onto a substrate within the processing chamber. PECVD is a CVD process whereby a plasma is ignited in the chamber to enhance the reaction between the precursors. PECVD may be accomplished utilizing an inductively coupled plasma source or a capacitively coupled plasma source.

The PECVD process may be used to process large area substrates, such as flat panel displays or solar panels. PECVD may also be used to deposit layers such as silicon based films for transistors and diodes for example. For large area substrates, delivering the process gases, together with the RF hardware utilized to ignite the plasma within the chamber, can be quite expensive on a per substrate basis. Therefore, there is a need in the art for a PECVD apparatus that reduces the cost of manufacturing devices on a per substrate basis.

### SUMMARY OF THE INVENTION

The present invention generally provides a linear PECVD apparatus. The apparatus is designed to process two substrates simultaneously so that the substrates share plasma sources as well as gas sources. The apparatus has a plurality of microwave sources centrally disposed within the chamber body of the apparatus. The substrates are disposed on opposite sides of the microwave sources with the gas sources disposed between the microwave sources and the substrates. The shared microwave sources and gas sources permit multiple substrates to be processed simultaneously and reduce the processing cost per substrate. It is to be understood that while description herein relates to a vertical system designed to process multiple substrates with a microwave plasma source, the embodiments herein are equally applicable to a system designed to process a single substrate as well or to a horizontally arranged system or to plasma sources other than microwave sources such as inductive plasma sources or capacitive plasma sources.

In one embodiment, an apparatus comprises one or more substrate supports disposed within a chamber body, a plurality of plasma sources located within the chamber body opposite the one or more substrate supports and a plurality of gas introduction tubes disposed within the chamber body between the plurality of plasma sources and the one or more substrate supports. The plurality of plasma sources are spaced from the one or more substrate supports by a distance that is between about 1.3 to about 3 times the distance between adjacent gas introduction tubes of the plurality of gas introduction tubes.

In another embodiment, an apparatus comprises one or more substrate supports disposed within a chamber body, a plurality of plasma sources located within the chamber body opposite the one or more substrate supports and a plurality of gas introduction tubes disposed within the chamber body between the plurality of plasma sources and the one or more substrate supports. The plurality of gas introduction tubes are spaced from the one or more substrate supports by about 0.2 and about 0.5 times the distance between adjacent plasma sources.

In another embodiment, an apparatus comprises one or more substrate supports disposed within a chamber body, a plurality of plasma sources located within the chamber body opposite the one or more substrate supports and a plurality of gas introduction tubes disposed within the chamber body between the plurality of plasma sources and the one or more substrate supports. The distance between adjacent plasma sources is between about 2 and about 4 times the distance between adjacent gas instruction tubes.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic representation of a processing system incorporating a linear plasma CVD apparatus according to an embodiment.

FIGS. 2A and 2B are schematic end and top views, respectively of the dual processing chambers 110A, 110B according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present invention generally relates to a linear PECVD apparatus. The apparatus is designed to process two substrates simultaneously so that the substrates share plasma sources as well as gas sources. The apparatus has a plurality of microwave sources centrally disposed within the chamber body of the apparatus. The substrates are disposed on opposite sides of the microwave sources with the gas sources disposed between the microwave sources and the substrates. The shared microwave sources and gas sources permit multiple substrates to be processed simultaneously and reduce the processing cost per substrate.

The embodiments herein are discussed with regards to a vertical in-line PECVD chamber available from AKT America, Inc., a subsidiary of Applied Materials, Inc., Santa Clara, Calif. It is to be understood that the embodiments discussed herein may be practiced in other chambers as well, including those sold by other manufacturers.

The plasma sources currently used in display and thin-film solar PECVD tools are parallel-plate reactors using capacitively coupled RF or VHF fields to ionize and dissociate process gases between the plate electrodes. One of the promising candidates for the next-generation flat-panel PECVD chambers are plasma reactors capable of processing two substrates at the same time by having two substrates in one “vertical” chamber and use “common” plasma- and gas sources for both substrates. This approach will not only increase the throughput of the system, but will also cut the cost of RF hardware and process gases (per throughput) as both the gas and RF power are shared by two substrates processed together.

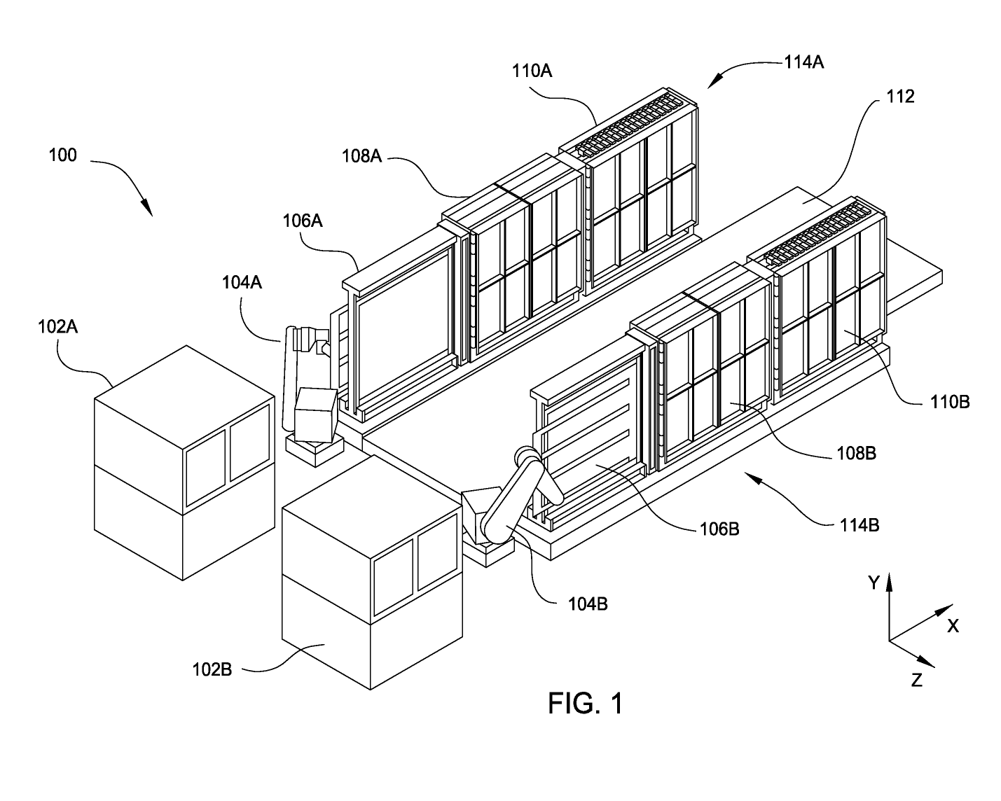

FIG. 1 is a schematic representation of a vertical, linear PECVD system 100 according to one embodiment. The system 100 may be sized to process substrates having a surface area of greater than about 90,000 mm² and able to process more than 90 substrates per hour when depositing a 2,000 Angstrom thick silicon nitride film. The system 100 preferably includes two separate process lines 114A, 114B coupled together by a common system control platform 112 to form a twin process line configuration/layout. A common power supply (such as an AC power supply), common and/or shared pumping and exhaust components and a common gas panel may be used for the twin process lines 114A, 114B. Each process line 114A, 114B may process more than 45 substrates per hour for a system total of greater than 90 substrates per hour. It is also contemplated that the system may be configured using a single process line or more than two process lines.

There are several benefits to the twin processing lines 114A, 114B for vertical substrate processing. Because the chambers are arranged vertically, the footprint of the system 100 is about the same as a single, conventional horizontal processing line. Thus, within approximately the same footprint, two processing lines 114A, 114B are present, which is beneficial to the manufacturer in conserving floor space in the fab. To help understand the meaning of the term “vertical”, consider a flat panel display. The flat panel display, such as a computer monitor, has a length, a width and a thickness. When the flat panel display is vertical, either the length or width extends perpendicular from the ground plane while the thickness is parallel to the ground plane. Conversely, when a flat panel display is horizontal, both the length and width are parallel to the ground plane while the thickness is perpendicular to the ground plane. For large area substrates, the length and width are many times greater than the thickness of the substrate.

Each processing line 114A, 114B includes a substrate stacking module 102A, 102B from which fresh substrates (i.e., substrates which have not yet been processed within the system 100) are retrieved and processed substrates are stored. Atmospheric robots 104A, 104B retrieve substrates from the substrate stacking modules 102A, 102B and place the substrates into a dual substrate loading station 106A, 106B. It is to be understood that while the substrate stacking module 102A, 102B is shown having substrates stacked in a horizontal orientation, substrates disposed in the substrate stacking module 102A, 102B may be maintained in a vertical orientation similar to how the substrates are held in the dual substrate loading station 106A, 106B. The fresh substrates are then moved into dual substrate load lock chambers 108A, 108B and then to a dual substrate processing chamber 110A, 110B. The substrates, following processing, then return through one of the dual substrate load lock chambers 108A, 108B to one of the dual substrate loading stations 106A, 106B, where they can be retrieved by one of the atmospheric robots 104A, 104B and returned to one of the substrate stacking modules 102A, 102B.

The plasma in a vertical reactor is generated by an array of linear sources placed between the two substrates. Arrays of linear plasma sources (i.e., plasma lines) and gas-feed lines have to be spread over the substrate's area to achieve a quasi-uniform plasma and reactive gas environment so that the films can be grown uniformly on the large “static” substrates. For a dynamic deposition system, the substrates are moved or scanned through the chamber during deposition past the one or several linear plasma and gas sources.

Different linear plasma-source technologies can be considered for the new “linear-plasma” CVD tools, (e.g., microwave, inductive, or capacitive plasma sources, or their combinations.) Each of the aforementioned technologies produce the plasma with different properties, and therefore one plasma technology may be more (or less) suitable than the others for a particular process/application. In general, the plasma lines can be powered by one generator (lines in series or in parallel), or by several generators (on one or both sides of the line). The best choice depends on the plasma technology, the size of available generator(s), and the chamber size (e.g., the ICP can easily use one low-frequency generator for several plasma lines, the UHF or VHF can use either one or more generators, while 2.45 GHz microwave will most likely use one or two generators per line).

In the embodiments disclosed herein, after the plasma-technology and power delivery selections, the spacing between the lines, substrate position, and projected gas-pressure can all determined. The plasma and gas lines spacing, substrate position, gas pressure, chemistry and gas flow all affect uniform processing over the large-area substrates. The embodiments discussed herein relate to the plasma and gas line layout, the plasma-process regime of operation and a method for the plasma and gas line spacing. The embodiments discussed herein are for a 2.45 GHz microwave powered plasma reactor, however, the embodiments can be scaled to accomodate: (i) for any plasma reactor using linear-plasma source technology, whether the plasma source is microwave, inductive or capacitive; (ii) in any type of CVD system, including vertical dual or single substrate chambers or horizontal single substrate chambers and (iii) with any substrate deposition mode, (i.e., static- or dynamic mode).

The embodiments discussed herein address the issue of non-uniform deposition in a large-area PECVD chamber, which uses linear-plasma source technology. The linear sources in general are inherently “non-uniform” in the direction perpendicular to the source axis. Uniform processing on large substrates can be achieved by either (1) “fine” spacing of plasma and process gas lines to form quasi-uniform plasma and reactive gas distribution over the substrate, or (2) by placing the substrate far away from the linear plasma/gas sources and/or operating at sufficiently low gas pressures—the first solution is costly, and the second has negative impact on deposition rates (i.e., reactor throughput) and film quality.

The embodiments discussed herein operate with “quasi-uniform” gas distribution within the processing chamber. The “quasi-uniform” gas distribution is achieved by using as many gas lines as possible with a non-uniform plasma made by as few plasma lines/sources as possible (the gas-lines are cheap relative to the plasma lines) and doing the deposition process in a “supply/gas limited regime”, (i.e., the plasma power/density in every place above the substrate, even in the density minima between the plasma lines, is sufficient to “break” all the reactive gas available.) Thus, a “spatially non-uniform plasma” across the plasma line can still provide a uniform deposition process. The distances between the plasma sources and gas lines need to be optimized for a particular process, gas chemistry, pressure and distance to the substrate.

The embodiments discussed herein can be used in any large-area PECVD process such as for dielectric film deposition for display or solar (thin-film and/or crystalline solar) panels, e.g., TFT gate-insulation and passivation, or passivation and anti-reflective coatings for solar cells. The embodiments discussed herein may be usable for intrinsic silicon deposition for TFTs used in displays, and/or diodes for photovoltaics applications. The plasma sources can also be used in dry etch or many other plasma surface treatments, such as polymer ashing, surface activations, etc., for large flat substrates.

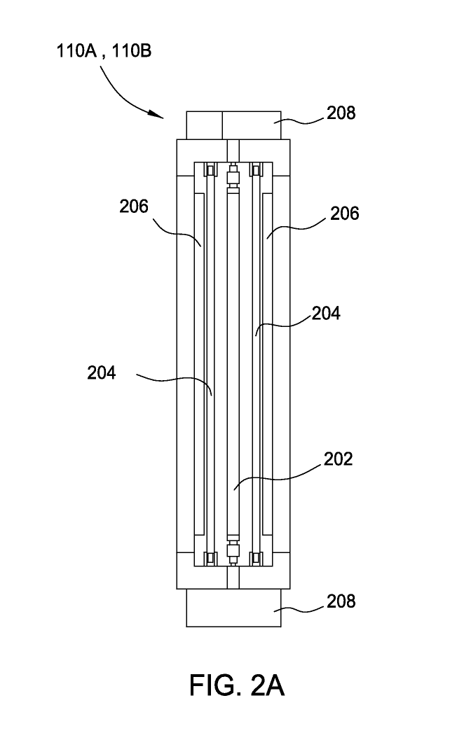

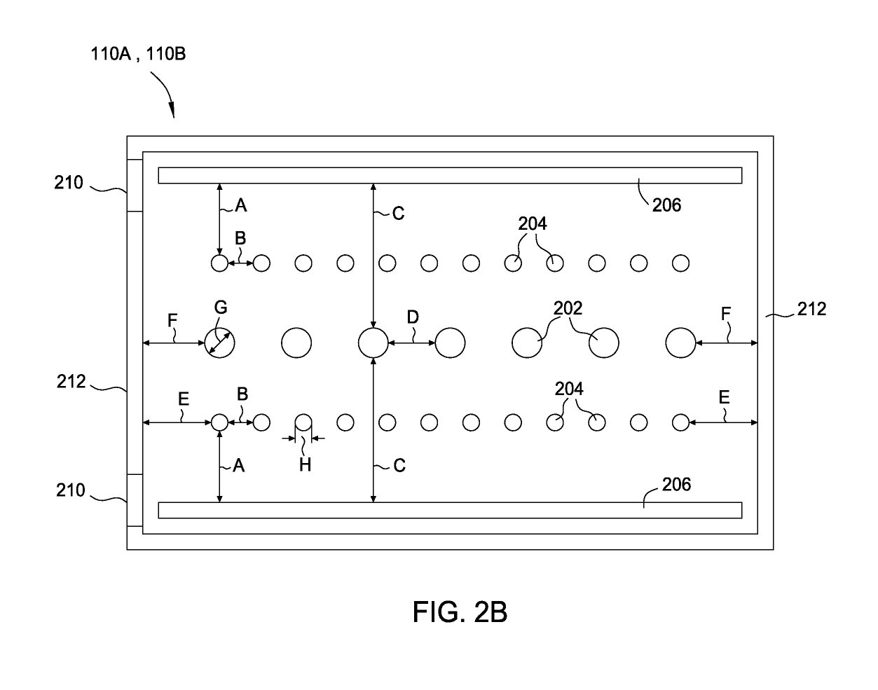

FIGS. 2A and 2B are schematic end and top views of the dual processing chambers 110A, 110B, respectively, according to one embodiment. The dual processing chambers 110A, 110B include a plurality of plasma sources 202, such as microwave antennas, disposed in a linear arrangement in the center of each processing chamber 110A, 110B. The plasma sources 202 extend vertically from a top of the processing chamber 110A, 110B to a bottom of the processing chamber 110A, 110B. Each plasma source 202 has a corresponding microwave power head 208 at both the top and the bottom of the processing chamber 110A, 110B that is coupled to the plasma source 202. Power may be independently applied to each end of the plasma source 202 through each power head 208. The plasma sources 202 may operate at a frequency within a range of 300 MHz and 300 GHz.

Each of the processing chambers 110A, 110B are arranged to be able to process two substrates, one on each side of the plasma sources 202. The substrates are held in place within the processing chamber by a substrate support 206 and a shadow frame (not shown). Gas introduction tubes 204 are disposed between the plasma sources 202 and the substrate support 206. The gas introduction tubes 204 extend vertically from the bottom to the top of the processing chamber 110A, 110B parallel to the plasma sources 202. The gas introduction tubes 204 permit the introduction of processing gases, such as silicon precursors and nitrogen precursors. While not shown in FIGS. 2A-2B, the processing chambers 110A, 110B may be evacuated through a pumping port located behind the substrate supports 206. The substrate supports 206 enter and exit the processing chamber 110A, 110B through sealable openings 210 formed through the chamber body.

FIG. 2B is a top view of the processing chamber 110A, 110B showing the layout of the plasma sources 202, gas introduction tubes 204 and substrate supports 206. The distance between adjacent plasma sources 202, between adjacent gas sources 204, between the gas sources 204 and the substrate support 206, between the plasma sources 202 and the substrate support 206 and the location of the gas sources 204 within the processing chamber 110A, 110B all affect the plasma distribution. In order to achieve uniform deposition, uniform plasma is needed according to the conventional wisdom. The inventors have discovered, however, that rather than uniform plasma, uniform gas flow will lead to uniform deposition.

During the deposition process, the amount of material deposited onto a substrate is directly related to the amount of material that is available to be deposited. For a PECVD process, the only source for the material to be deposited is the processing gas introduced through the gas introduction tubes 204. So long as the gas that is available to react and deposit onto the substrate is evenly distributed within the processing chamber 110A, 110B and is entirely used during the deposition process, the film deposited onto the substrate will be uniform in thickness and properties. Of course, sufficient plasma sources 202 need to be present in order to ignite the plasma. Applicants have discovered the ratio of plasma sources 202 to total gas introduction tubes 204 within the chamber 110A, 110B should be between about 1:5 to about 1:6.

Applicants have also discovered that the arrangement of the gas introduction tubes 204, plasma sources 202 and substrate supports 206 of the processing chamber 110A, 110B will affect the deposition uniformity. In the embodiment shown in FIG. 2B, seven plasma sources 202 are shown, but it is to be understood that more or less plasma sources 202 may be present based upon the desired chamber size. For example, for a chamber used to process substrates having at least one dimension (i.e., length or width) that is greater than about 2 meters, between eight and fourteen total plasma sources 202 may be used. Additionally, while twenty-four gas sources 204 are shown in FIG. 2B, more or less gas introduction tubes 204 may be present based upon the desired chamber size. For example, for a chamber used to process substrates having at least one dimension (i.e., length or width) that is greater than about 3 meters, between forty and eighty total gas introduction tubes 204 may be used.

As shown in FIG. 2B, the plasma sources 202 are centrally located within the processing chamber 110A, 110B and the substrate supports 206 are permitted to enter and exit the processing chamber 110A, 110B through openings 210 formed through the chamber body. The substrate supports 206 are disposed on opposite sides of the plasma sources 202. The gas introduction tubes 204 are disposed between the plasma sources 202 and the substrate supports 206. In order to ensure that the gas is evenly distributed within the processing chamber, adjacent gas introduction tubes 204 are equally spaced apart by a distance represented by arrows “B” and each gas introduction tube 204 is evenly spaced from the substrate support 206 by a distance represented by arrows “A”. Similarly, the plasma sources 202 are all equally spaced from the substrate supports 206 by a distance shown by arrows “C” while adjacent plasma sources 202 are spaced apart by a distance shown by arrows “D”.

Within the processing chamber 110A, 110B, the number of gas introduction tubes 204 present on each side of the centrally located plasma sources 202 is equal. Additionally, the gas introduction tubes 204 that are closest to the end walls 212 of the chamber body are spaced a greater distance as shown by arrows “E” from the end walls 212 than the plasma sources 202 located closest to the end walls 212, as shown by arrows “F”. If the gas introduction tubes 204 are disposed closer to the end walls 212 than the plasma sources 202, then not all of the reactive gas introduced through the gas introduction tubes 204 closest to the end walls 212 will be consumed and white powder, in the case of a silicon based deposition process, will deposit on undesired locations within the processing chamber 110A, 110B. Each of the gas introduction tubes 204 has a diameter “H” that is between about one-quarter of an inch and about five-eighths of an inch. Each of the plasma sources 202 has a diameter that is between about 20 mm and about 50 mm.

The location of the plasma sources 202, gas introduction tubes 204 and substrate supports 206 relative to each other affects the gas distribution as well as whether sufficient energy is present to consume (i.e., excite and react) all of the gas introduced through the gas introduction tubes 204. Applicants have discovered that the plasma sources 202 should be spaced from each substrate support 206 by a distance that is between about 1.3 to about 3 times the distance between adjacent gas introduction tubes 204. Additionally, the gas introduction tubes 204 should be spaced from the substrate supports 206 by a distance that 0.4 to 2 times the distance between adjacent gas introduction tubes 204. The plasma sources 202 should be spaced from the substrate supports 206 by a distance that is between about 0.03 to about 1.5 the distance between adjacent plasma sources 202. The plasma sources 202 should be spaced from the substrate supports 206 by a distance that is between about 2.3 and about 2.67 times the distance between the gas introduction tubes 204 and the substrate supports 206. The gas introduction tubes 204 should be spaced from the substrate supports 206 by a distance that is between about 0.2 and about 0.5 times the distance between adjacent plasma sources 202. The distance between adjacent plasma sources 202 should be between about 2and about 4 times the distance between adjacent gas introduction tubes 204. Thus, the gas introduction tubes 204 should be spaced from the substrate supports 204 by about 0.2 and about 0.5 times the distance between adjacent plasma sources 202. Additionally, the plasma sources 202 should be spaced from the substrate supports 206 by a distance that is between about 1.3 to about 3 times the distance between adjacent gas introduction tubes 204.

By processing two substrates simultaneously, the plasma sources (i.e., microwave antennas) and gas introduction sources can be shared and substrate throughput can be increased. By minimizing the number of plasma sources while ensuring a uniform gas distribution within the processing chamber, a uniform film can be deposited onto the substrate at a lower cost.

While the foregoing is directed to embodiments of the present invention, other and further embodiments of the invention may be devised without departing from the basic scope thereof, and the scope thereof is determined by the claims that follow.

1. An apparatus, comprising:
a chamber body;
one or more substrate supports disposed within the chamber body;
a plurality of plasma sources located within the chamber body opposite the one or more substrate supports; and
a plurality of gas introduction tubes disposed within the chamber body between the plurality of plasma sources and the one or more substrate supports, the plurality of plasma sources are spaced from the one or more substrate supports by a distance that is between about 1.3 to about 3 times the distance between adjacent gas introduction tubes of the plurality of gas introduction tubes.

2. The apparatus of claim 1, wherein the plurality of gas introduction tubes are spaced from the one or more substrate supports by a distance that is between about 0.4 to about 2 times the distance between adjacent gas introduction tubes.

3. The apparatus of claim 2, wherein the plurality of plasma sources are spaced from the one or more substrate supports by a distance that is between about 0.3 to about 1.5 the distance between adjacent plasma sources.

4. The apparatus of claim 3, wherein the plurality of plasma sources are spaced from the one or more substrate supports by a distance that is about 2.67 times the distance between the plurality of gas introduction tubes and the one or more substrate supports.

5. The apparatus of claim 4, the plurality of gas introduction tubes are spaced from the one or more substrate supports by a distance that is between about 0.2 and about 0.5 times the distance between adjacent plasma sources.

6. The apparatus of claim 5, wherein the distance between adjacent plasma sources is between about 2 and about 4 times the distance between adjacent gas instruction tubes.

7. The apparatus of claim 6, wherein the chamber body is sized to process substrates having at least one dimension that is greater than about 2 meters.

8. The apparatus of claim 7, wherein the plurality of microwave sources comprises between about 8 and about 16 microwave sources.

9. The apparatus of claim 8, wherein the plurality of gas introduction tubes comprises between about 20 to about 40 gas introduction tubes disposed between the plurality of microwave sources each substrate support of the one or more substrate supports.

10. The apparatus of claim 9, wherein each gas tube of the plurality of gas tubes has a diameter of between about one-quarter of an inch and about five-eighths of an inch.

11. The apparatus of claim 10, wherein each microwave sources has a diameter of between about 20 mm and about 50 mm.

12. The apparatus of claim 11, wherein the plurality of plasma sources comprises a plurality of microwave sources.

13. An apparatus, comprising:
a chamber body;
one or more substrate supports disposed within the chamber body;
a plurality of plasma sources located within the chamber body opposite the one or more substrate supports; and
a plurality of gas introduction tubes disposed within the chamber body between the plurality of plasma sources and the one or more substrate supports, the plurality of gas introduction tubes are spaced from the one or more substrate supports by about 0.2 and about 0.5 times the distance between adjacent plasma sources.

14. The apparatus of claim 13, wherein the plurality of plasma sources are spaced from the one or more substrate supports by a distance that is between about 1.3 to about 3 times the distance between adjacent gas introduction tubes of the plurality of gas introduction tubes.

15. The apparatus of claim 14, wherein the plurality of plasma sources comprises between about 8 and about 16 microwave sources.

16. The apparatus of claim 15, wherein the plurality of gas introduction tubes comprises between about 20 to about 40 gas introduction tubes disposed between the plurality of microwave sources each substrate support of the one or more substrate supports.

17. The apparatus of claim 16, wherein each gas tube of the plurality of gas tubes has a diameter of between about one-quarter of an inch and about five-eighths of an inch.

18. The apparatus of claim 17, wherein each microwave sources has a diameter of between about 20 mm and about 50 mm.

19. An apparatus, comprising:
a chamber body;
one or more substrate supports disposed within the chamber body;
a plurality of plasma sources located within the chamber body between the one or more substrate supports; and
a plurality of gas introduction tubes disposed within the chamber body between the plurality of plasma sources and the one or more substrate supports, the distance between adjacent plasma sources is between about 2 and about 4 times the distance between adjacent gas instruction tubes.

20. The apparatus of claim 19, wherein the plurality of plasma sources comprises between about 8 and about 16 microwave sources, wherein the plurality of gas introduction tubes comprises between about 20 to about 40 gas introduction tubes disposed between the plurality of microwave sources each substrate support of the one or more substrate supports, wherein each gas tube of the plurality of gas tubes has a diameter of between about one-quarter of an inch and about five-eighths of an inch, and wherein each microwave sources has a diameter of between about 20 mm and about 50 mm.
